(19) United States
(12) Patent Application Publication
(10) Pub. No.: US 2024/0387414 A1
(43) Pub. Date: Nov. 21, 2024

(54) POWER MODULE

(71) Applicant: DENSO CORPORATION, Kariya-city (JP)

(72) Inventors: Masakazu SHIGA, Kariya-City (JP); Yoshitaka SUZUKI, Kariya-city (JP); Atsuyuki HIRUMA, Kariya-city (JP)

(73) Assignee: DENSO CORPORATION, Kariya-city (JP)

(21) Appl. No.: 18/665,812

(22) Filed: May 16, 2024

(30) Foreign Application Priority Data
May 18, 2023 (JP) 2023-082574

(51) Int. Cl. H01L 23/64; H01L 23/367; H01L 23/498; H01L 23/66; H02P 27/06

(52) U.S. Cl. CPC H01L 23/642; H01L 23/367; H01L 23/49838; H01L 23/66; H02P 27/06

(57) ABSTRACT

In a power module, an upper-arm switching device and a lower-arm switching device are provided. The lower-arm switching device is located to face the upper-arm switching device. A first dielectric member, which has a first stray capacitance, is located in a space defined by the upper-arm switching device and the lower-arm switching device. A second dielectric member, which has a second stray capacitance, is located to be separated from the space. The second stray capacitance is different from the first stray capacitance.

### CROSS-REFERENCE TO RELATED APPLICATION

This application is based on and claims the benefit of priority from Japanese Patent Application No. 2023-82574, the disclosure of which is incorporated in its entirety herein by reference.

### TECHNICAL FIELD

The present disclosure relates to power modules.

### BACKGROUND

Japanese Patent Application Publications No. 2007-181351 disclose a technology for reducing common-mode noise generated from a power module.

Specifically, the technology disclosed in the patent publication discloses a pair of an upper-arm insulated gate bipolar transistor (IGBT) chip and a lower-arm IGBT chip of the power module (see FIG. 4 of the patent publication). The collector of one of the upper- and lower-arm IGBT chips is connected to a first copper pattern, and the emitter of one of the upper- and lower-arm IGBT chips is connected to a second copper pattern, i.e., a mount pattern. Conversely, the emitter of the other of the upper- and lower-arm IGBT chips is connected to the first copper pattern, and the collector of the other of the upper- and lower-arm IGBT chips is connected to the second copper pattern. This enables the area of the first copper pattern to be smaller, making it possible to reduce a stray capacitance between the first copper pattern and the second copper pattern. This enables reduction of a common-mode current, i.e., common-mode noise, due to the stray capacitance between the first and second copper patterns.

### SUMMARY

The above patent publication however may not address any measures against normal-mode noise and common-mode noise generated from one or more components other than the power module. This may therefore result in such a power module requiring, as additional noise measurement components, one or more X capacitors for reduction of normal-mode noise and one or more Y capacitors for reduction of common-mode noise generated from one or more components other than the power module. Accordingly, the known technology typically disclosed in the patent publication may require improvement in reduction of adverse effects due to noise.

From this viewpoint, the present disclosure seeks to provide power modules, each of which is capable of reducing, without additional noise measurement components, adverse effects due to noise.

A first exemplary aspect of the present disclosure provides a power module. The power module includes an upper-arm switching device, and a lower-arm switching device located to face the upper-arm switching device. The power module includes a first dielectric member having a first stray capacitance. The first dielectric member is located in a space defined by the upper-arm switching device and the lower-arm switching device. The power module includes a second dielectric member having a second stray capacitance. The second dielectric member is located to be separated from the space. The second stray capacitance is different from the first stray capacitance.

The difference in stray capacitance between the first and second dielectric members of the power module enables noise, such as normal-mode noise or common-mode noise, to be collected in the power module. The power module of the first exemplary embodiment therefore reduces noise without additional noise-measurement components.

A second exemplary aspect of the present disclosure provides a power module. The power module includes a switch unit. The switch unit includes a pair of upper- and lower-arm switches connected in series, a first input portion connected to a positive electrode of a power supply, a second input portion connected to a negative electrode of the power supply, and an output portion connected to a load. The power module includes at least one dielectric member having an adjusted stray capacitance and located at least one of (i) between the first and second input portions and (ii) between at least one of the first and second input portions and a member having a ground potential. The at least one dielectric member constitutes at least one route that transfers at least one of normal-mode noise and common-mode noise into the power module.

This configuration of the power module according to the second exemplary aspect enables the at least one of normal-mode noise and common-mode noise to be collected into the power module through the at least one route. The power module of the second exemplary embodiment therefore reduces the at least one of normal-mode noise and common-mode noise.

Note that each of the power modules of the first and second exemplary aspects can additionally include one or more physical X capacitors and one or more physical Y capacitors as physical noise-measurement components.

### BRIEF DESCRIPTION OF THE DRAWINGS

Other aspects of the present disclosure will become apparent from the following description of embodiments with reference to the accompanying drawings in which:

FIG. 1 is a circuit diagram schematically illustrating an example of the configuration of a motor drive circuit according to the first embodiment of the present disclosure;

FIG. 2 is an exploded perspective view schematically illustrating the appearance of a power module illustrated in FIG. 1;

FIG. 3 is a circuit diagram schematically illustrating an equivalent circuit of each power module according to the first embodiment;

FIG. 4 is a sectional view of each power module according to the first embodiment;

FIG. 5 is a circuit diagram illustrating how the motor drive circuit equipped with the power modules works;

FIG. 6 is an exploded perspective view schematically illustrating the appearance of a power module according to the second embodiment of the present disclosure;

FIG. 7 is a circuit diagram schematically illustrating an equivalent circuit of each power module according to the second embodiment;

FIG. 8 is a sectional view of each power module according to the second embodiment;

FIG. 9 is a circuit diagram illustrating how a motor drive circuit equipped with the power modules according to the second embodiment works;

FIG. 10 is an exploded perspective view schematically illustrating the appearance of a power module according to the third embodiment of the present disclosure;

FIG. 11 is a circuit diagram schematically illustrating an equivalent circuit of each power module according to the third embodiment;

FIG. 12 is a sectional view of each power module according to the third embodiment;

FIG. 13 is a circuit diagram illustrating how a motor drive circuit equipped with the power modules according to the third embodiment works;

FIG. 14 is an exploded perspective view schematically illustrating the appearance of a power module according to the fourth embodiment of the present disclosure;

FIG. 15 is a circuit diagram schematically illustrating an equivalent circuit of each power module according to the fourth embodiment;

FIG. 16 is a sectional view of each power module according to the fourth embodiment;

FIG. 17 is a sectional view of each power module according to the fifth embodiment of the present disclosure;

FIG. 18 is a sectional view of each power module according to the sixth embodiment of the present disclosure;

FIG. 19 is a circuit diagram schematically illustrating an equivalent circuit of each power module according to the seventh embodiment of the present disclosure; and

FIG. 20 is a sectional view of each power module according to the seventh embodiment.

### DETAILED DESCRIPTION OF EMBODIMENTS

The following describes embodiments of the present disclosure with reference to the accompanying drawings. In the embodiments, descriptions of like parts between the embodiments, to which like reference characters are assigned, are omitted or simplified to avoid redundant descriptions.

### First Embodiment

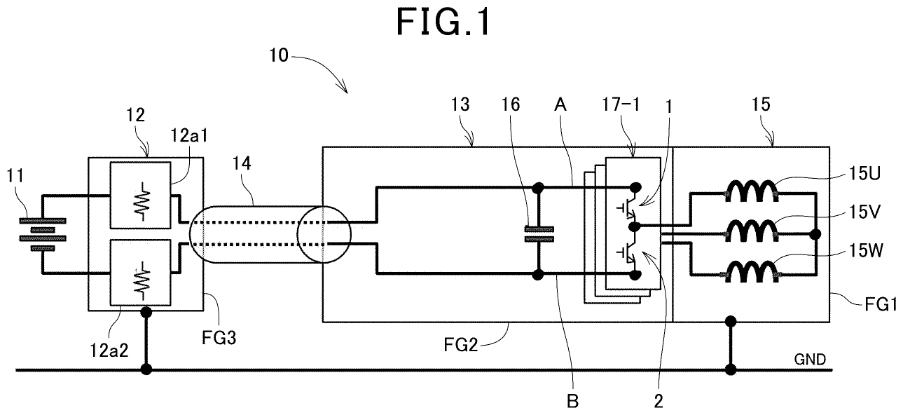

FIG. 1 is a circuit diagram illustrating an example of the configuration of a motor drive circuit 10 according to the first embodiment of the present disclosure.

The motor drive circuit 10 is configured to convert direct-current (DC) power supplied from a DC power supply 11 that serves as a hybrid-vehicle (HV) power source into alternating-current (AC) power, and drive, based on the converted AC power, an AC motor 15. The motor drive circuit 10 includes an inverter 13 and DC buses, such as PN cables, 14, and can include a line impedance stabilization network (LISN) 12 connected to the DC power supply 11. The LISN 12 includes a positive stabilization unit 12a1 and a negative stabilization unit 12a2, and is configured to stabilize an impedance of the DC power supply 11 as seen from the inverter 13. The inverter 13 is connected to the LISN 12 through the DC buses 14.

The inverter 13 includes a smoothing capacitor 16 and power modules 17-1 for converting a DC voltage as the DC power into an AC voltage as the AC power. Each power module 17-1 includes a plurality of switching devices.

For example, the AC motor 15 is a three-phase AC motor 15 comprised of three-phase (UVW-phase) coils 15U, 15V, and 15W, and the inverter includes three power modules 17-1 provided for the respective three-phase coils 15U, 15V, and 15W. For example, each power module 17-1 is comprised of a pair of switching devices.

The AC motor 15, the inverter 13, and the LISN 12 are connected to, for example, a common ground GND. For example, the AC motor 15 has a neutral point to which the three-phase coils 15U, 15V, and 15W are commonly connected, and has a frame ground FG1. The frame ground FG1 is, for example, connected to the common ground GND. The inverter 13 has a frame ground FG2, and the frame ground FG2 is, for example, connected to the common ground GND. The LISN 12 has a frame ground FG3, and the frame ground FG3 is, for example, connected to the common ground GND.

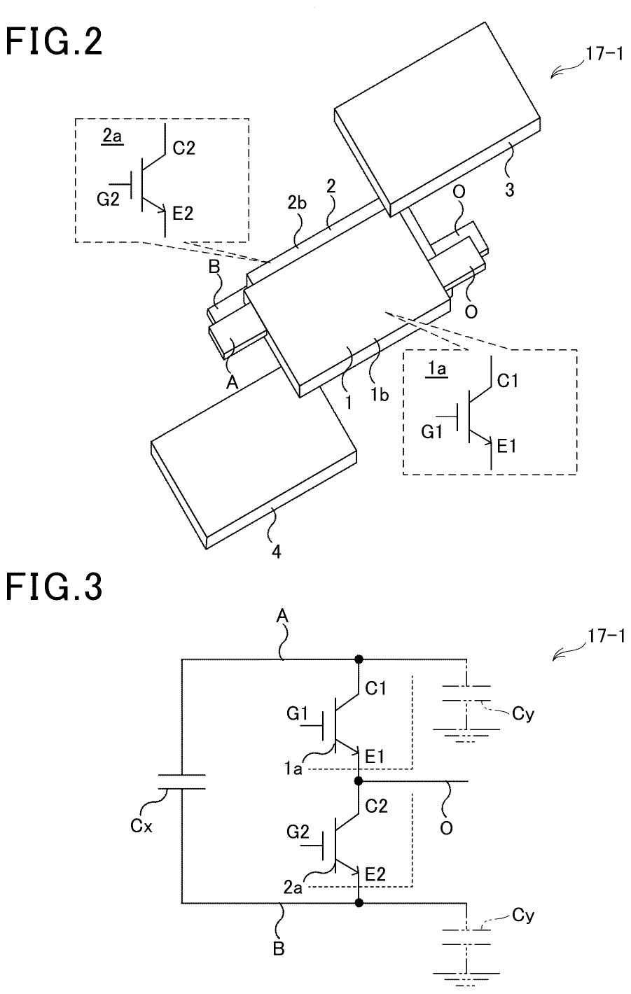

FIG. 2 is an exploded perspective view schematically illustrating the appearance of a power module 17-1.

Each power module 17-1 includes a first power card 1 serving as, for example, an upper-arm switching device, a second power card 2 serving as, for example, a second switching device, a first heatsink 3, and a second heatsink 4.

The first power card 1 is comprised of an upper-arm switch 1a, a casing 1b, a conductive input electrode A, and a conductive output electrode O. The casing 1b encloses the upper-arm switch 1a. The input electrode A of the first power card 1 serves as input of power thereto, and the output electrode O of the first power card 1 serves as output of power therefrom.

The second power card 2 is comprised of a lower-arm switch 2a, a casing 2b, a conductive input electrode B, and a conductive output electrode O. The casing 2b encloses the lower-arm switch 2a. The input electrode B of the second power card 2 serves as input of power thereto, and the output electrode O of the second power card 2 serves as output of power therefrom.

The DC power supply 11 has a positive electrode and a negative electrode. The positive electrode of the DC power supply 11 is connected to the input electrode A of the first power card 1 of each power module 17-1 through the positive stabilization unit 12a1 of the LISN 12, and the negative electrode of the DC power supply 11 is connected to the input electrode B of the second power card 2 of each power module 17-1 through the negative stabilization unit 12a2 of the LISN 12.

Each of the first and second power cards 1 and 2, i.e., the casings 1b and 2b thereof, has, for example, a substantially rectangular plate-like shape, and opposing first and second major surfaces. The first power card 1 and the second power card 2 are disposed to be adjacent to one another with the second major surface of the first power card 1 faces the first major surface of the second power card 2.

The first heatsink 3 serves as a cooling member provided for the first power card 1; the first heatsink 3 for example cools the first power card 1. The first heatsink 3 is located on the first major surface of the first power card 1, which is opposite to the second major surface of the first power card 1 facing the second power card 2. The second heatsink 4 serves as a cooling member provided for the second power card 2; the second heatsink 4 for example cools the second power card 2. The second heatsink 4 is located on the second major surface of the second power card 2, which is opposite to the first major surface of the second power card 2 facing the first power card 1.

Each of the first and second heatsinks 3 and 4 has, for example, a substantially rectangular plate-like shape, and is comprised of a conductive member, such as an aluminum member and/or a metallic member.

For example, the upper-arm switch 1a is an IGBT switch comprised of a collector electrode, i.e., a collector C1, an emitter electrode, i.e., an emitter E1, and a gate electrode, i.e., a gate G1.

The semiconductor device 1a is configured such that the emitter E1 is exposed from the casing 1b to constitute the first major surface of the casing 1b as an emitter surface, and the collector C1 is exposed from the casing 1b to constitute the second major surface as a collector surface.

Similarly, the lower-arm switch 2a is an IGBT switch comprised of a collector electrode, i.e., a collector C2, an emitter electrode, i.e., an emitter E2, and a gate electrode, i.e., a gate G2.

The semiconductor device 2a is configured such that the emitter E2 is exposed from the casing 2b to constitute the first major surface of the casing 2b as an emitter surface, and the collector C2 is exposed from the casing 2b to constitute the second major surface as a collector surface.

Each of the casings 1b and 2b has a pair of opposing long sides and a pair of short sides.

The input electrode A of the first power card 1 is connected to the collector C1, and is arranged to protrude from one of the short sides of the casing 1b, and the output electrode O of the first power card 1 is connected to the emitter E1, and is arranged to protrude from the other of the short sides of the casing 1b. Similarly, the input electrode B of the second power card 2 is connected to the emitter E2, and is arranged to protrude from one of the short sides of the casing 2b while facing the input electrode A, and the output electrode O of the second power card 2 is connected to the collector C2, and is arranged to protrude from the other of the short sides of the casing 2b while facing the output electrode O of the first power card 1. The emitter E1 of the upper-arm switch 1a is connected to the collector C2 of the lower-arm switch 2a.

The input electrode B of the second power card 2 of each power module 17-1 serves as a common signal ground of the corresponding power module 17-1.

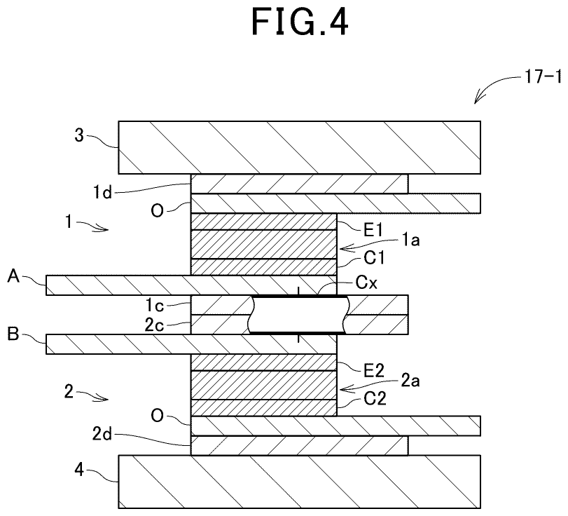

The following describes an internal configuration of the power module 17-1 with reference to FIGS. 3 and 4.

FIG. 3 illustrates an equivalent circuit of each power module 17-1 according to the first embodiment. FIG. 4 is a sectional view of each power module 17-1 according to the first embodiment.

The first power card 1 is comprised of, as illustrated in FIG. 4, a first dielectric member 1c and a second dielectric member 1d.

The first dielectric member 1c, which has, for example, a substantially rectangular plate-like shape, is arranged between the input electrode A of the first power card 1 and the input electrode B of the second power card 2. The first dielectric member 1c can constitute a part of the casing 1b or can constitute an individual component separated from the casing 1b.

The second dielectric member 1d, which has, for example, a substantially rectangular plate-like shape, is arranged between the output electrode O of the first power card 1 and the first heatsink 3. The second dielectric member 1d can be interpreted as a dielectric member arranged elsewhere than the location between the upper- and lower-arm switches 1a and 2a.

Each of the first and second dielectric members 1c and 1d contains one or more materials having an insulation performance, such as one or more organic materials, one or more inorganic materials, or combination of one or more organic materials and one or more inorganic materials. The inorganic materials can be selected from silicon oxide (SiO₂), silicon nitride (Si₃N₄), silicon oxynitride (Si₃N₄), aluminum oxide (Al₂O₃), aluminum nitride (AlN), silicon carbide (SIC), silicon carbonitride (SiCN), carbon-doped silicon oxide (SiCO), borosilicate glass, silica glass, and other similar materials. The organic materials can be selected from polyimide, epoxy resin, benzocyclobutenone resin, polyamide, phenol resin, fluororesin, liquid crystal polymer, polyamideimide, polybenzoxazole, cyanate resin, aramid resin, polyolefin, polyester, and other similar materials.

The second power card 2 is comprised of, as illustrated in FIG. 4, a first dielectric member 2c and a second dielectric member 2d.

The first dielectric member 2c, which has, for example, a substantially rectangular plate-like shape, is arranged between the input electrode B of the second power card 2 and the input electrode A of the first power card 1. The second dielectric member 2d, which has, for example, a substantially rectangular plate-like shape, is arranged between the output electrode O of the second power card 2 and the second heatsink 4. The second dielectric member 2d can be interpreted as a dielectric member arranged elsewhere than the location between the upper- and lower-arm switches 1a and 2a.

Like the first and second dielectric members 1c and 1d, each of the first and second dielectric members 2c and 2d contains one or more materials having an insulation performance.

The first dielectric members 1c and 2c are located to be in contact with or close to each other, which serves as a dielectric-member assembly (1c, 2c). The first dielectric members 1c and 2c can be inherently integrated with one another as a one-piece member or can be separated from one another.

Specifically, as illustrated in FIG. 4, each power module 17-1 is configured such that the first heatsink 3, the second dielectric member 1d, the output electrode O of the first power card 1, the upper-arm switch 1a, the input electrode A of the first power card 1, the first dielectric member 1c, the first dielectric member 2c, the input electrode B of the second power card 2, the lower-arm switch 2a, the output electrode O of the second power card 2, the second dielectric member 2d, and the second heatsink 4 are aligned, i.e., stacked, in a predetermined direction, which will be referred to as an alignment direction, i.e., a stacking direction.

The first heatsink 3 is mounted on the first major surface of the casing 1b of the upper-arm switch 1a, which is opposite to the second major surface of the casing 1b of the upper-arm switch 1a; the second major surface of the casing 1b of the upper-arm switch 1a is located to be closer to the first dielectric member 1c than the first major surface of the casing 1b of the upper-arm switch 1a is. The second heatsink 4 is mounted on the second major surface of the casing 2b of the lower-arm switch 2a, which is opposite to the first major surface of the casing 2b of the lower-arm switch 2a; the first major surface of the casing 2b of the lower-arm switch 2a is located to be closer to the first dielectric member 2c than the second major surface of the casing 2b of the lower-arm switch 2a is.

That is, the first dielectric member 1c of the first power card 1 and the first dielectric member 2c of the second power card 2 are disposed in a space defined by the input electrode A of the first power card 1 and the input electrode B of the second power card 2.

The second dielectric member 1d is located to be separated from the space in which the first dielectric members 1c and 2c are disposed, and the second dielectric member 2d is located to be separated from the space in which the first dielectric members 1c and 2c are disposed.

In particular, the first dielectric member 1c of the first power card 1 is disposed to be closer to the input electrode A of the first power card 1 than the first dielectric member 2c of the second power card 2 is, and the first dielectric member 2c of the second power card 2 is disposed to be closer to the input electrode B of the second power card 2 than the first dielectric member 1c of the first power card 1 is.

This arrangement of the first dielectric member 1c results in a stray capacitance C between the input electrode A of the first power card 1 and the input electrode B of the second power card 2. Similarly, this arrangement of the first dielectric member 2c results in a stray capacitance C between the input electrode A of the first power card 1 and the input electrode B of the second power card 2.

Each of the first dielectric members 1c and 2c has opposing first and second major surfaces. The first major surface of the first dielectric member 1c faces the upper-arm switch 1a, and the second major surface of the first dielectric member 1c faces the first major surface of the first dielectric member 2c, i.e., the lower-arm switch 2a. The first major surface of the first dielectric member 2c faces the second major surface of the first dielectric member 1c, i.e., the upper-arm switch 1a, and the second major surface of the first dielectric member 2c faces the lower-arm switch 2a.

Note that, in the specification, a phrase “elements face one another” or similar phrases means (i) the elements directly face one another, and (ii) the elements indirectly face one another with one or more other elements located between the elements.

The stray capacitance C arising from the dielectric-member assembly (1c, 2c) between the input electrode A of the first power card 1 and the input electrode B of the second power card 2 can be defined in accordance with the following formulas (1) to (3) assuming that the first dielectric members 1c and 2c are located to be in contact with each other:

$$1 / C = 1 / C 11 + 1 / C 21 \qquad ( 1 )$$

$$C 11 = {ε}_{0} {ε}_{S 1} S / d 1 \qquad ( 2 )$$

$$C 21 = {ε}_{0} {ε}_{S 2} S / d 2 \qquad ( 3 )$$

where:
C represents, as the stray capacitance, a capacitance of the dielectric-member assembly (1c, 2c);
C11 represents a stray capacitance of the first dielectric member 1c;

C21 represents a stray capacitance of the first dielectric member 2c;
ε₀ represents a vacuum permittivity;
ε_{S1} represents a relative permittivity of the first dielectric member 1c;
ε_{S2} represents a relative permittivity of the first dielectric member 2c;

S represents a surface area of a portion of each of the input electrodes A and B, which exactly faces the dielectric-member assembly;
d1 represents a thickness of the first dielectric member 1c in the stacking direction of the power module 17-1; and
d2 represents a thickness of the first dielectric member 2c in the stacking direction of the power module 17-1.

That is, the stray capacitance C is represented as a series-connection of the stray capacitance C11 of the first dielectric member 1c and the stray capacitance C21 of the first dielectric member 2c. If the material of the first dielectric member 1c is identical to that of the first dielectric member 2c, the relative permittivity ε_{S1} is the same as the relative permittivity ε_{S2} of the first dielectric member 2c. The first dielectric members 1c and 2c can be integrally comprised of a single dielectric member. If the first dielectric members 1c and 2c are located to be close to each other, the stray capacitance C arising from the dielectric-member assembly (1c, 2c) between the input electrode A of the first power card 1 and the input electrode B of the second power card 2 can be defined in accordance with the following formulas (4) and (5):

$$1 / C = 1 / C 11 + 1 / C 1 a + 1 / C 21 \qquad ( 4 )$$

$$C 1 a = {ε}_{0} {ε}_{Sa} S / da \qquad ( 5 )$$

where:

C1a represents a capacitance of air between the first dielectric members 1c and 2c;

ε_{Sa} represents a relative permittivity of air between the first dielectric members 1c and 2c; and
da represents a thickness of air between the first dielectric members 1c and 2c in the stacking direction.

That is, the stray capacitance C is represented as a series-connection of the stray capacitance C11 of the first dielectric member 1c, the capacitance of air, and the stray capacitance C21 of the first dielectric member 2c.

The surface area S of the portion of each of the input electrodes A and B, which faces the dielectric-member assembly, can be interpreted as the surface area of the portion of the dielectric-member assembly, which faces each of the input electrodes A and B.

The stray capacitance C arising from the dielectric-member assembly (1c, 2c) between the input electrode A of the first power card 1 and the input electrode B of the second power card 2 results in a capacitor Cx being formed between the input electrode A of the first power card 1 and the input electrode B of the second power card 2. The capacitor Cx can be interpreted as a pseudo-X capacitor, which can be interpreted as a capacitor different from a physical X capacitor. A pseudo or equivalent situation generated by the stray capacitance C represents, for example, a situation where, without physical X capacitors, the stray capacitance C formed by the first dielectric members 1c and 2c equivalently serves as a physical X capacitor. Such a pseudo-X capacitor can be interpreted as an across-the-line capacitor that reduces and/or suppresses normal-mode noise.

The second dielectric member 1d of the first power card 1 is disposed between the output electrode O of the first power card 1 and the first heatsink 3, resulting in a stray capacitance therebetween. Similarly, the second dielectric member 2d of the second power card 2 is disposed between the output electrode O of the second power card 2 and the second heatsink 4, resulting in a stray capacitance therebetween.

Each power module 17-1 is configured such that the stray capacitance C11 arising from the first dielectric member 1c is set to be different from the stray capacitance arising from the second dielectric member 1d. Specifically, the stray capacitance C11 arising from the first dielectric member 1c is set to be higher than the stray capacitance arising from the second dielectric member 1d. The stray capacitance C11 arising from the first dielectric member 1c can be interpreted as a stray capacitance arising from the first dielectric member 1c between the input electrode A of the first power card 1 and the input electrode B of the second power card 2. The stray capacitance arising from the second dielectric member 1d can be interpreted as a stray capacitance arising from the second dielectric member 1d between the first heatsink 3 and the output electrode O of the first power card 1.

Similarly, each power module 17-1 is configured such that the stray capacitance C21 arising from the first dielectric member 2c is set to be different from the stray capacitance arising from the second dielectric member 2d. Specifically, the stray capacitance C21 arising from the first dielectric member 2c is set to be higher than the stray capacitance arising from the second dielectric member 2d. The stray capacitance C21 arising from the first dielectric member 2c can be interpreted as a stray capacitance arising from the first dielectric member 2c between the input electrode A of the first power card 1 and the input electrode B of the second power card 2. The stray capacitance arising from the second dielectric member 2d can be interpreted as a stray capacitance arising from the second dielectric member 2d between the second heatsink 4 and the output electrode O of the second power card 2.

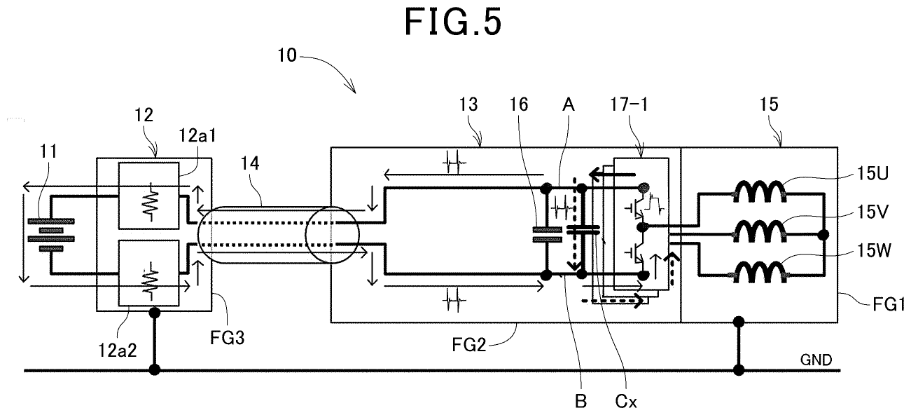

FIG. 5 is a circuit diagram illustrating how the motor drive circuit 10 equipped with the power modules 17-1 works.

Referring to FIG. 5, the capacitor Cx is formed between the input electrode A of the first power card 1 and the input electrode B of the second power card 2 for each power module 17-1.

On and off switching operations of the upper- and lower-arm switches 1a and 2a of each power module 17-1, which has the capacitor Cx formed therein, enable the DC voltage supplied from the DC power supply 11 to be converted into the AC voltage, and the AC voltage is applied to the AC motor 15.

The capacitor Cx of each power module 17-1 has lower values of impedance in a predetermined high frequency range than values of impedance in a frequency range lower than the predetermined high frequency range. The stray capacitance C arising from the dielectric-member assembly (1c, 2c), which forms the capacitor Cx, is higher than each of the stray capacitances arising from the second dielectric members 1d and 2d. This results in a route of normal-mode noise, i.e., high-frequency noise, being formed between the input electrode A of the first power card 1 and the input electrode B of the second power card 2. That is, the capacitor Cx serves as either a route transferring high-frequency noise from the input electrode A of the first power card 1 to the input electrode B of the second power card 2 or a route transferring high-frequency noise from the input electrode B of the second power card 2 to the input electrode A of the first power card 1.

This configuration of the motor drive circuit 10 enables a part of normal-mode noise generated from, for example, the switch 1a of each power module 17-1 to flow into the capacitor Cx (see, for example, dashed line in FIG. 5) to accordingly prevent the part of normal-mode noise from flowing out the input side of the motor drive circuit 10 (see, for example, solid line in FIG. 5), resulting in the part of normal-mode noise being collected in the corresponding power module 17-1. Resistance components included in each power module 17-1 can attenuate the normal-mode noise collected in the corresponding power module 17-1.

The motor drive circuit 10 therefore achieves reduction and/or suppression of normal-mode noise without additionally including one or more physical X capacitors as noise-measurement components, making it possible to reduce erroneous operations of peripheral devices around the inverter 13. The motor drive circuit 10, which eliminates the need of physical X capacitors, results in a simpler configuration, making it possible to improve the reliability of the motor drive circuit 10 and the fabrication yield of the motor drive circuits 10.

### Second Embodiment

The following describes a motor drive circuit 10A according to the second embodiment. The structure and/or functions of the motor drive circuit 10A according to the second embodiment are mainly identical to those of the motor drive circuit 10 except for the following points. The following therefore describes mainly the different points.

The inverter 13 of the second embodiment includes power modules 17-2 in place of the power modules 17-1.

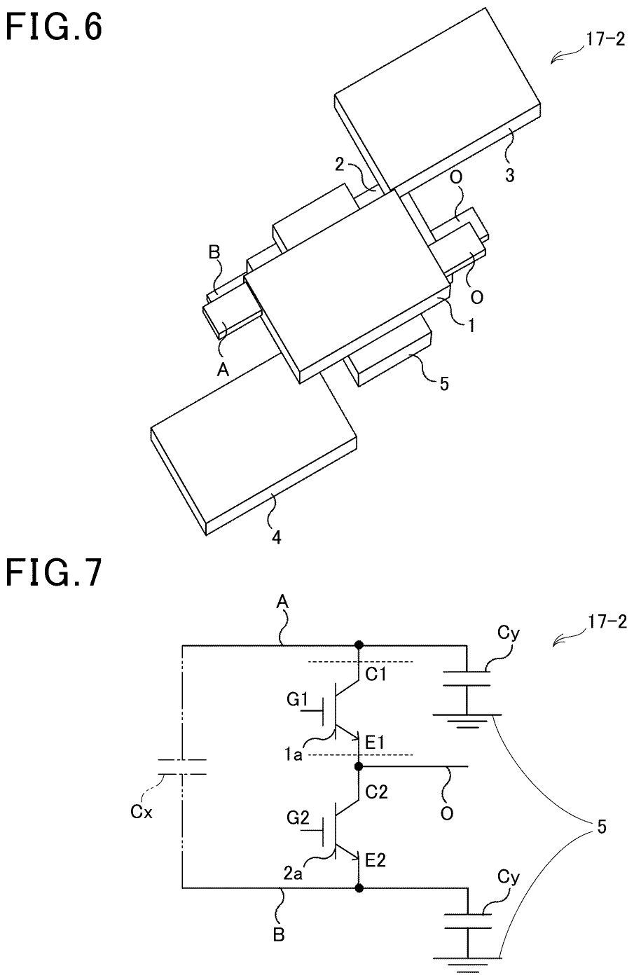

FIG. 6 is an exploded perspective view schematically illustrating the appearance of a power module 17-2.

Each power module 17-2 includes a third heatsink 5 in addition to the first power card 1, second power card 2, first heatsink 3, and second heatsink 4. The third heatsink 5 serves as a cooling member disposed between the first and second power cards 1 and 2. Specifically, the third heatsink 5 serves as a cooling member disposed between the upper- and lower-arm switches 1a and 2a.

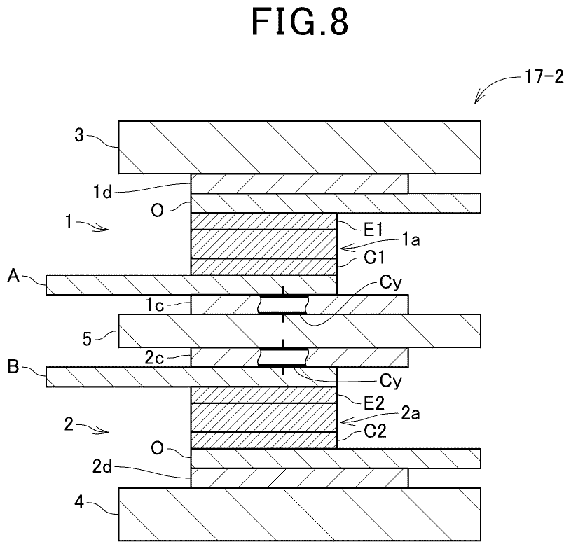

The following describes an internal configuration of the power module 17-2 with reference to FIGS. 7 and 8.

FIG. 7 illustrates an equivalent circuit of each power module 17-2 according to the second embodiment. FIG. 8 is a sectional view of each power module 17-2 according to the second embodiment.

Referring to FIG. 8, the third heatsink 5 is disposed between the first dielectric member 1c and the first dielectric member 2c. The third heatsink 5 can be interpreted as a cooling member disposed between the upper- and lower-arm switches 1a and 2a. The third heatsink 5 has, for example, a substantially rectangular plate-like shape, and is comprised of a conductive member, such as an aluminum member and/or a metallic member. The third heatsink 5 serves as a ground having a ground potential, and is connected to, for example, the frame ground FG2 of the inverter 13.

The first dielectric member 1c is arranged between the upper-arm switch 1a and the third heatsink 5. The first dielectric member 2c is arranged between the packaged lower-arm switch 2a and the third heatsink 5.

Each power module 17-2 is configured such that the stray capacitance arising from the first dielectric member 1c is set to be higher than the stray capacitance arising from the second dielectric member 1d. The stray capacitance arising from the first dielectric member 1c can be interpreted as a stray capacitance arising from the first dielectric member 1c between the third heatsink 5 and the input electrode A of the first power card 1. Similarly, each power module 17-2 is configured such that the stray capacitance arising from the first dielectric member 2c is set to be higher than the stray capacitance arising from the second dielectric member 2d. The stray capacitance arising from the first dielectric member 2c can be interpreted as a stray capacitance arising from the first dielectric member 2c between the third heatsink 5 and the input electrode B of the second power card 2.

Each of the stray capacitances arising from the first dielectric members 1c and 2c can be defined in accordance with the corresponding one of the formulas (2) and (3) set forth above. The stray capacitance arising from the first dielectric member 1c results in a first capacitor Cy formed between the input electrode A of the first power card 1 and the ground of the third heatsink 5, and the stray capacitance arising from 25 the first dielectric member 2c results in a second capacitor Cy formed between the input electrode B of the second power card 2 and the ground of the third heatsink 5. Each of the first and second capacitors Cy can be interpreted as a pseudo-Y capacitor, which can be interpreted as a capacitor different from a physical Y capacitor. A pseudo or equivalent situation generated by the first capacitor Cy represents, for example, a situation where, without physical Y capacitors, a capacitance formed by the first dielectric member 1c included in the power module 17-2 equivalently serves as a physical Y capacitor. Similarly, a pseudo or equivalent situation generated by the second capacitor Cy represents, for example, a situation where, without physical Y capacitors, a capacitance formed by the first dielectric member 2c included in the power module 17-2 equivalently serves as a physical Y capacitor. Such pseudo-Y capacitors can be interpreted as line-bypass capacitors that reduce and/or suppress common-mode noise.

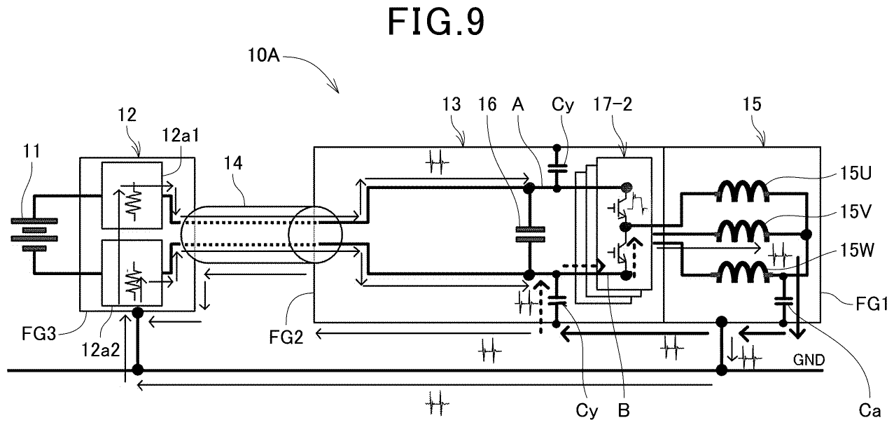

FIG. 9 is a circuit diagram illustrating how the motor drive circuit 10A equipped with the power modules 17-2 works.

Referring to FIG. 9, the first capacitor Cy is formed between the input electrode A of the first power card 1 and the ground of the third heatsink 5 in each power module 17-2. Similarly, the second capacitor Cy is formed between the input electrode B of the second power card 2 and the ground of the third heatsink 5 in each power module 17-2.

On and off switching operations of the upper- and lower-arm switches 1a and 2a of each power module 17-2 of the motor drive circuit 10A, which has the first and second capacitors Cy formed therein, enable the DC voltage supplied from the DC power supply 11 to be converted into the AC voltage, and the AC voltage is applied to the AC motor 15.

Each of the first and second capacitors Cy has lower values of impedance in a predetermined high frequency range than values of impedance in a frequency range lower than the predetermined high frequency range. The stray capacitances arising from the first dielectric members 1c and 2c, which form the first and second capacitors Cy, are higher than the stray capacitances arising from the second dielectric members 1d and 2d, respectively. This results in a route of common-mode noise, i.e., high-frequency noise, being formed between the input electrode A of the first power card 1 and the ground of the third heatsink 5, and a route of common-mode noise, i.e., high-frequency noise, formed between the input electrode B of the second power card 2 and the ground of the third heatsink 5. That is, each of the first and second capacitors Cy serves as a corresponding one of (i) a route transferring high-frequency noise from the ground of the third heatsink 5 to the input electrode A of the first power card 1 and (ii) a route transferring high-frequency noise from the ground of the heatsink 5 to the input electrode B of the second power card 2. Because the ground of the third heatsink 5 is connected to the frame ground FG2 of the inverter 13, the ground according to the second embodiment can be interpreted as the frame ground FG2 of the inverter 13.

This configuration of the motor drive circuit 10A enables a part of common-mode noise, which is for example transferred through a stray capacitance Ca between the frame ground FG1 of the AC motor 15 and the common ground GND to the frame ground FG2 of the inverter 13 and/or the third heatsink 5 while the motor drive circuit 10A is operating, to flow into each of the first and second capacitors Cy (see dashed lines in FIG. 9) to accordingly prevent the part of common-mode noise from flowing out the input side of the motor drive circuit 10A (see, for example, solid lines in FIG. 9). This results in the part of common-mode noise being collected in each power module 17-2. Resistance components included in each power module 17-2 can attenuate the common-mode noise collected in the corresponding power module 17-2.

The motor drive circuit 10A therefore achieves reduction and/or suppression of common-mode noise without additionally including one or more physical Y capacitors as noise-measurement components, making it possible to reduce erroneous operations of peripheral devices around the inverter 13. The motor drive circuit 10A, which eliminates the need of physical Y capacitors, results in a simpler configuration, making it possible to improve the reliability of the motor drive circuit 10A and the fabrication yield of the motor drive circuits 10A.

In each power module 17-2, arranging the switches 1a and 2a closer to the third heatsink 5 aims to increase the cooling capability of the switches 1a and 2a. This configuration enables the first dielectric members 1c and 2c to respectively serve as the first and second capacitors Cy that serve as routes through which common-mode noise can be transferred, making it possible to efficiently reduce the common-mode noise.

### Third Embodiment

The following describes a motor drive circuit 10B according to the third embodiment. The structure and/or functions of the motor drive circuit 10B according to the third embodiment are substantially identical to those of the motor drive circuit 10 except for the following points. The following therefore describes mainly the different points.

The inverter 13 of the third embodiment includes power modules 17-3 in place of the power modules 17-1.

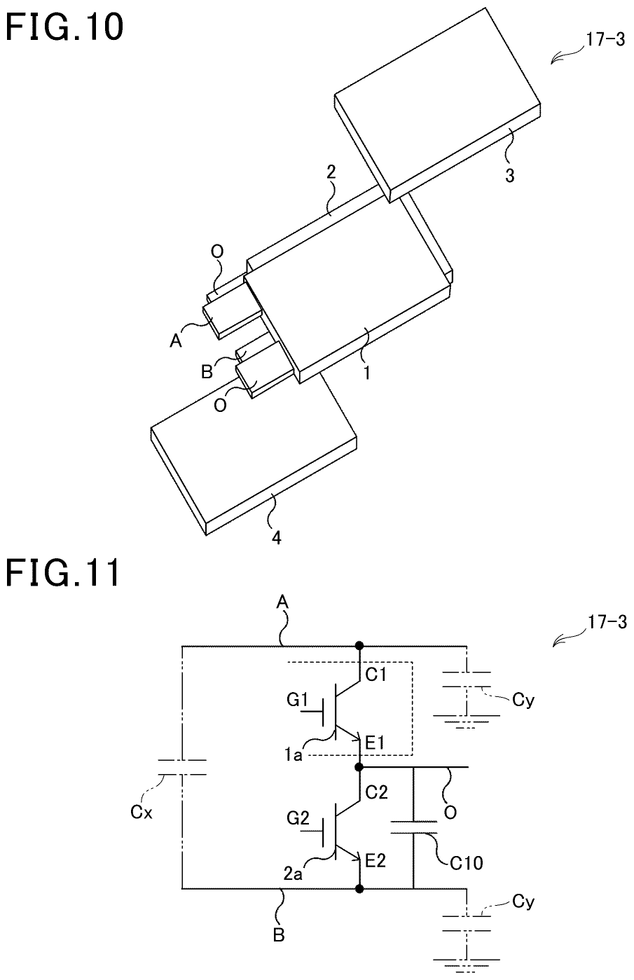

FIG. 10 is an exploded perspective view schematically illustrating the appearance of a power module 17-3.

As compared with the first power card 1 according to the first embodiment, the first power card 1 of each power module 17-3 is stacked over the second power card 1 with the arrangement of the collector C1 and emitter E1 being reversed as compared with the arrangement of the collector C2 and emitter E2 of the second power card 2. In addition, the location of the input and output electrodes of each of the first and second power cards 1 and 2 of the third embodiment is different from the location of the input and output electrodes of the corresponding one of the first and second power cards 1 and 2 according to the first embodiment.

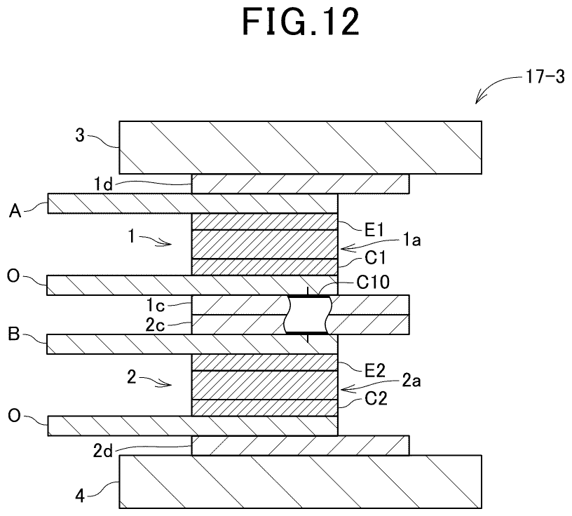

The following describes an internal configuration of the power module 17-3 with reference to FIGS. 11 and 12.

FIG. 11 illustrates an equivalent circuit of each power module 17-3 according to the third embodiment. FIG. 12 is a sectional view of each power module 17-3 according to the third embodiment.

Referring to FIG. 12, each power module 17-3 is configured such that the first heatsink 3, the second dielectric member 1d, the input electrode A of the first power card 1, the upper-arm switch 1a, the output electrode O of the first power card 1, the first dielectric member 1c, the first dielectric member 2c, the input electrode B of the second power card 2, the lower-arm switch 2a, the output electrode O of the second power card 2, the second dielectric member 2d, and the second heatsink 4 are stacked in a predetermined direction, which will be referred to as a stacking direction.

The semiconductor device 1a is configured such that the collector C1 is exposed from the casing 1b to constitute the first major surface of the casing 1b as a collector surface, and the emitter E1 is exposed from the casing 1b to constitute the second major surface as an emitter surface.

That is, the arrangement of the emitter and collector surfaces of the upper-arm switch 1a of the third embodiment is reversed as compared with the arrangement of the emitter and collector surfaces of the upper-arm switch 1a of the first embodiment.

The input and output electrodes A and O of the first power card 1 of each power module 17-3 are arranged to protrude from one of the short sides of the package 1b. The input and output electrodes B and O of the second power card 2 of each power module 17-3 are arranged to protrude from the same short side of the package 2b while facing the output and input electrodes O and A of the first package 17-1.

The first dielectric member 1c is arranged between the output electrode O of the first power card 1 and the input electrode B of the second power card 2, and the first dielectric member 2c is arranged between the output electrode O of the first power card 1 and the input electrode B of the second power card 2. In other words, the first dielectric member 1c is arranged between the output electrode O of the first power card 1 and the second power card 2, and the first dielectric member 2c is arranged between the output electrode O of the first power card 1 and the second power card 2. The first dielectric member 1c is located to be closer to the output electrode O of the first power card 1 than the first dielectric member 2c is.

Like the first embodiment, each power module 17-3 is configured such that the stray capacitance C11 arising from the first dielectric member 1c is set to be higher than the stray capacitance arising from the second dielectric member 1d. The stray capacitance C11 arising from the first dielectric member 1c can be interpreted as a stray capacitance arising from the first dielectric member 1c between the output electrode O of the first power card 1 and the input electrode B of the second power card 2. The stray capacitance C11 arising from the first dielectric member 1c can be interpreted as a stray capacitance arising from the first dielectric member 1c between the emitter E1 of the first power card 1 and the emitter E2 of the second power card 2.

The stray capacitance C11 arising from the first dielectric member 1c can be defined in accordance with the above formula (2), and the stray capacitance C21 arising from the first dielectric member 2c can be defined in accordance with the above formula (3). The stray capacitance C arising from the series-connection of the stray capacitance C11 of the first dielectric member 1c and the stray capacitance C21 of the first dielectric member 2c results in a capacitor C10 formed between the output electrode O of the first power card 1 and the input electrode B of the second power card 2, i.e., the signal ground of the power module 17-3. The capacitor C10 can be interpreted as a pseudo snubber capacitor, which can be interpreted as a capacitor different from a physical snubber capacitor. A pseudo or equivalent situation generated by the snubber capacitor C10 represents, for example, a situation where, without physical snubber capacitors, a capacitance formed by the combination of the first dielectric members 1c and 2c included in the power module 17-3 equivalently serves as a physical snubber capacitor. Such a pseudo snubber capacitor can be interpreted as a capacitor that absorbs high-frequency noise generated by on/off switching of the upper-arm switch 1a and/or the lower-arm switch 2a.

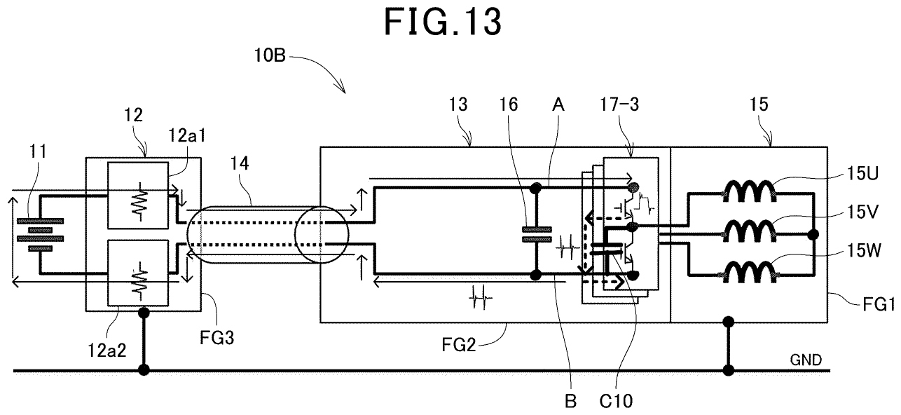

FIG. 13 is a circuit diagram illustrating how the motor drive circuit 10B equipped with the power modules 17-3 works.

Referring to FIG. 13, each power module 17-3 is configured such that the capacitor C10 is formed between the output electrode O, i.e., the emitter E1, of the first power card 1 and the input electrode B of the second power card 2, i.e., the signal ground of the corresponding power module 17-3.

On and off switching operations of the upper- and lower-arm switches 1a and 2a of each power module 17-3 of the motor drive circuit 10B, which has the capacitor C10 formed therein, enable the DC voltage supplied from the DC power supply 11 to be converted into the AC voltage, and the AC voltage is applied to the AC motor 15.

The stray capacitances arising from the first dielectric members 1c and 2c, which form the capacitor C10, are higher than the stray capacitances arising from the second dielectric members 1d and 2d, respectively. This results in a route of high-frequency noise being formed between the output electrode O of the first power card 1 of each power module 17-3 and the signal ground of the corresponding power module 17-3. That is, the capacitor C10 serves as a route transferring high-frequency noise between the output electrode O of the first power card 1 of each power module 17-3 and the signal ground of the corresponding power module 17-3.

This configuration of the motor drive circuit 10B enables a part of noise generated from the switches 1a and 2a of each power module 17-3 to flow into the capacitor C10 (see dashed line in FIG. 13) to accordingly prevent the part of noise from flowing out the input side of motor drive circuit 10B (see, for example, solid line in FIG. 13), resulting in the part of noise being collected in the corresponding power module 17-3. Resistance components included in each power module 17-3 can attenuate the noise collected in the corresponding power module 17-3.

The motor drive circuit 10B therefore achieves reduction and/or suppression of noise generated due to switching operations of the switches 1a and 2a without additionally including one or more physical snubber capacitors as noise-measurement components, making it possible to reduce erroneous operations of peripheral devices around the inverter 13.

The motor drive circuit 10B, which eliminates the need of physical snubber capacitors, results in a simpler configuration, making it possible to improve the reliability of the motor drive circuit 10B and the fabrication yield of the motor drive circuits 10B.

If one or more snubber capacitors were provided in the inverter 13, the one or more snubber capacitors might serve as one or more heating elements so that heat-dissipation measurement might be needed for the inverter 13.

In contrast, each power module 17-3 of the motor drive circuit 10B of the third embodiment is configured to include the pseudo snubber capacitor C10. This configuration enables the first and second heatsinks 3 and 4 included in each power module 17-3 to dissipate heat generated from the pseudo snubber capacitor C10, resulting in no need of heat-dissipation measurement for physical snubber capacitors. This therefore results in the motor drive circuit 10B having a simpler configuration.

As described above, each power module 17-3 includes the pseudo snubber capacitor C10 formed for the second power card 2 (the lower-arm switch 2a), i.e., formed between the output electrode O of the first power card 1, i.e., the output electrode O of the second power card 2, and the signal ground of the corresponding power module 17-3, i.e., the input electrode B of the second power card 2, but the present disclosure is not limited thereto. Specifically, each power module 17-3 can include a pseudo snubber capacitor formed for the first power card 1 (the upper-arm switch 1a), i.e., formed between the input electrode A and the output electrode O of the first power card 1.

### Fourth embodiment

The following describes a motor drive circuit 10C according to the fourth embodiment. The structure and/or functions of the motor drive circuit 10C according to the fourth embodiment are substantially identical to those of the motor drive circuit 10 except for the following points. The following therefore describes mainly the different points.

The inverter 13 of the fourth embodiment includes power modules 17-4 in place of the power modules 17-1.

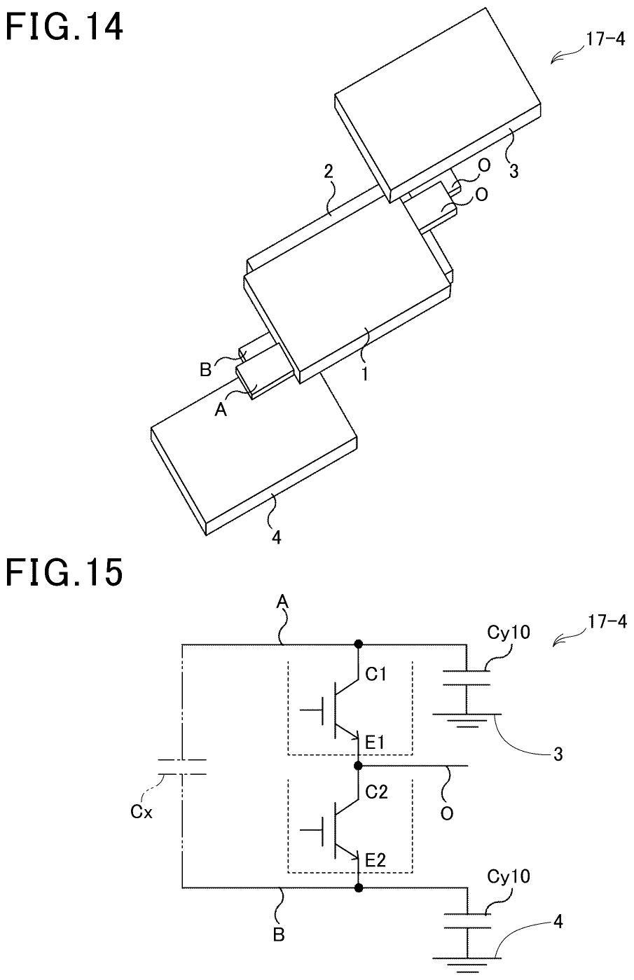

FIG. 14 is an exploded perspective view schematically illustrating the appearance of a power module 17-4.

As compared with the first power card 1 according to the first embodiment, the first power card 1 of each power module 17-4 is stacked over the second power card 2 with the arrangement of the collector C1 and emitter E1 being reversed as compared with the arrangement of the collector C1 and emitter E1 of the first power card 1 of each power module 17-1 according to the first embodiment. Specifically, the collector C1 of the first power card 1 is arranged to be closer to the first heatsink 3 than the emitter E1 of the first power card 1 is, and the emitter E1 of the first power card 1 is arranged to be closer to the second power card 2 than the collector C1 of the first power card 1 is.

The second power card 2 of each power module 17-4 is stacked below the first power card 1 with the arrangement of the collector C2 and emitter E2 being reversed as compared with the arrangement of the collector C2 and emitter E2 of the second power card 2 of each power module 17-1 according to the first embodiment. Specifically, the emitter E2 of the second power card 2 is arranged to be closer to the second heatsink 4 than the collector C2 of the second power card 2 is, and the collector C2 of the second power card 2 is arranged to be closer to the first power card 1 than the collector C2 of the second power card 2 is.

That is, the arrangement of the emitter and collector surfaces of the upper-arm switch 1a of the fourth embodiment is reversed as compared with the arrangement of the emitter and collector surfaces of the upper-arm switch 1a of the first embodiment. Additionally, the arrangement of the emitter and collector surfaces of the lower-arm switch 2a of the fourth embodiment is reversed as compared with the arrangement of the emitter and collector surfaces of the lower-arm switch 2a of the first embodiment.

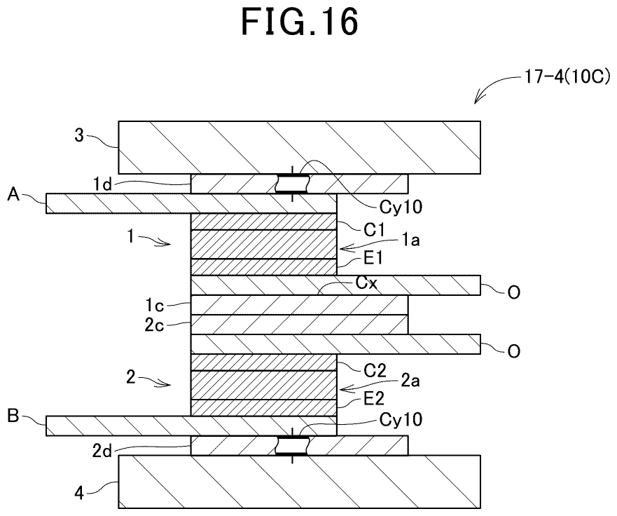

The following describes an internal configuration of the power module 17-4 with reference to FIGS. 15 and 16.

FIG. 15 illustrates an equivalent circuit of each power module 17-4 according to the fourth embodiment. FIG. 16 is a sectional view of each power module 17-4 according to the fourth embodiment.

Referring to FIG. 16, each power module 17-4 is configured such that the first heatsink 3, the second dielectric member 1d, the input electrode A of the first power card 1, the upper-arm switch 1a, the output electrode O of the first power card 1, the first dielectric member 1c, the first dielectric member 2c, the output electrode O of the second power card 2, the lower-arm switch 2a, the input electrode B of the second power card 2, the second dielectric member 2d, and the second heatsink 4 are aligned, i.e., stacked, in a predetermined direction, which will be referred to as an alignment direction, i.e., a stacking direction.

Each power module 17-4 of the fourth embodiment differs from the corresponding power module 17-1 of the first embodiment in that the second dielectric member 1d is arranged between the first heatsink 3 and the input electrode A of the first power card 1, and the second dielectric member 2d is arranged between the second heatsink 4 and the input electrode B of the second power card 2.

Additionally, each power module 17-4 of the fourth embodiment differs from the corresponding power module 17-1 of the first embodiment in that the stray capacitance arising from the second dielectric member 1d is set to be higher than the stray capacitance arising from the first dielectric member 1c, and the stray capacitance arising from the second dielectric member 2d is set to be higher than the stray capacitance arising from the first dielectric member 2c. In particular, each of the first and second heatsinks 3 and 4 serves as a ground having a ground potential, and is connected to, for example, the frame ground FG2 of the inverter 13.

The stray capacitance arising from each of the second dielectric members 1d and 2d can be defined in accordance with the above formula (1). The stray capacitance arising from the second dielectric member 1d results in a first capacitor Cy10 formed between the first heatsink 3 and the input electrode A of the first power card 1, and the stray capacitance arising from the second dielectric member 2d results in a second capacitor Cy10 formed between the second heatsink 4 and the input electrode B of the second power card 2.

Each of the first and second capacitors Cy10 can be interpreted as a pseudo-Y capacitor, which is similar to the first capacitors Cy according to the second embodiment.

Specifically, each of the first and second capacitors Cy10 has lower values of impedance in a predetermined high frequency range than values of impedance in a frequency range lower than the predetermined high frequency range. The stray capacitances arising from the second dielectric members 1d and 2d, which form the first and second capacitors Cy10, are higher than the stray capacitances arising from the first dielectric members 1c and 2c, respectively. This results in a route of common-mode noise, i.e., high-frequency noise, being formed between the input electrode A of the first power card 1 and the first heatsink 3, and a route of common-mode noise, i.e., high-frequency noise, formed between the input electrode B of the second power card 2 and the second heatsink 4.

That is, the first capacitor Cy10 serves as a route transferring high-frequency noise from the ground of the first heatsink 3 to the input electrode A of the first power card 1, and the second capacitor Cy10 serves as a route transferring high-frequency noise from the ground of the second heatsink 4 to the input electrode B of the second power card 2. Because the ground of each of the first and second heatsinks 3 and 4 is connected to the frame ground FG2 of the inverter 13, the ground according to the fourth embodiment can be interpreted as the frame ground FG2 of the inverter 13.

As described above, the above configuration of each power module 17-4 according to the fourth embodiment, which forms the pseudo-Y capacitors Cy10 like the second embodiment without including the third heatsink 5, achieves the same advantageous effects as stated for the second embodiment. Additionally, the above configuration of each power module 17-4 according to the fourth embodiment, which forms the pseudo-Y capacitors Cy10 like the second embodiment without including the third heatsink 5, results in the motor drive circuit 10C having a simpler configuration, making it possible to improve the reliability of the motor drive circuit 10C.

### Fifth Embodiment

The following describes a motor drive circuit 10D according to the fifth embodiment. The structure and/or functions of the motor drive circuit 10D according to the fifth embodiment are mainly identical to those of the motor drive circuit 10 except for the following points. The following therefore describes mainly the different points.

The inverter 13 of the fifth embodiment includes power modules 17-5 in place of the power modules 17-1.

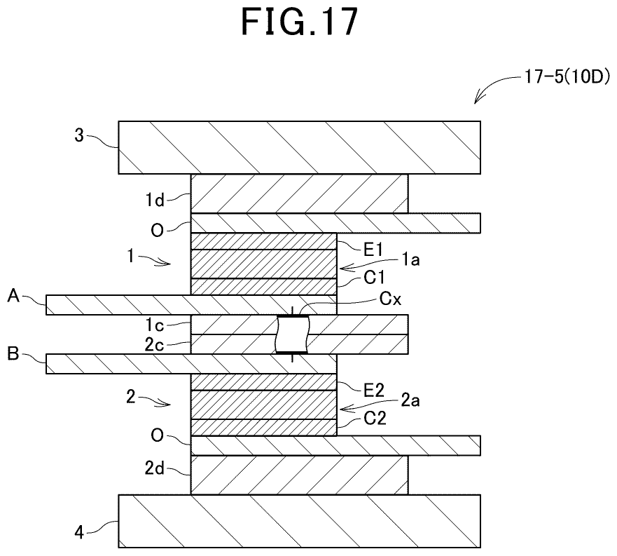

FIG. 17 is a sectional view of each power module 17-5 according to the fifth embodiment.

Referring to FIG. 17, each power module 17-5 is configured such that the thickness of each of the first dielectric members 1c and 2c in the stacking direction is smaller than the thickness of the corresponding one of the second dielectric members 1d and 2d in the stacking direction.

Specifically, the thickness of the first dielectric member 1c in the stacking direction is smaller than the thickness of the second dielectric member 1d in the stacking direction, and the thickness of the first dielectric member 2c in the stacking direction is smaller than the thickness of the second dielectric member 2d in the stacking direction.

More specifically, each of the first and second dielectric members 1c and 1d of the first power card 1 has opposing first and second major surfaces; the first major surface of the first dielectric member 1c faces the upper-arm switch 1a, and the second major surface of the second dielectric member 1d faces the upper-arm switch 1a. At that time, the thickness of the first dielectric member 1c in the stacking direction is smaller than the thickness of the second dielectric member 1d in the stacking direction on condition that
(I) The surface area S of the portion of the first dielectric member 1c of the dielectric-member assembly, which faces the input electrode A, is identical to the surface area of a portion of the second dielectric member 1d, which exactly faces the upper-arm switch 1a
(II) The relative permittivity ε_{S1} of the first dielectric member 1c is set to be equal to the relative permittivity of the second dielectric member 1d

Similarly, each of the first and second dielectric members 2c and 2d of the second power card 2 has opposing first and second major surfaces; the second major surface of the first dielectric member 2c faces the packaged lower-arm switch 2a, and the first major surface of the second dielectric member 2d faces the packaged lower-arm switch 2a. At that time, the thickness of the first dielectric member 2c in the stacking direction is smaller than the thickness of the second dielectric member 2d in the stacking direction on condition that
(I) The surface area S of the portion of the first dielectric member 2c of the dielectric-member assembly, which faces the input electrode B, is identical to the surface area of a portion of the second dielectric member 2d, which exactly faces the lower-arm switch 2a
(II) The relative permittivity ε_{S2} of the second dielectric member 2c is set to be equal to the relative permittivity of the second dielectric member 2d

As described above, a stray capacitance CK of a dielectric member having a surface area SK and a thickness dK can be defined in the following formula of CK=ε₀ε_{S}SK/dK where ε_{S} represents a relative permittivity of the dielectric member. That is, the stray capacitance of each dielectric member is inversely proportional to the thickness of the corresponding dielectric member, so that a decrease in the thickness of the first dielectric member 1c results in the stray capacitance C1 arising from of the first dielectric member 1c increasing. The same applies to the first dielectric member 2c.

Making smaller the thickness of each of the first dielectric members 1c and 2c enables each power converter 17-5 to have formed a capacitor Cx between the input electrode A of the power card 1 and the input electrode B of the power card 2. The capacitor Cx can be interpreted as a pseudo-X capacitor, which can be interpreted as a capacitor different from a physical X capacitor.

This configuration of the motor drive circuit 10D enables a part of normal-mode noise generated from the switches 1a and 2a of each power module 17-5 to flow into the capacitor Cx to accordingly prevent the part of normal-mode noise from flowing out the input side of the motor drive circuit 10D, resulting in the part of normal-mode noise being collected in the corresponding power module 17-5. Resistance components included in each power module 17-5 can attenuate the normal-mode noise collected in the corresponding power module 17-5.

The motor drive circuit 10D therefore achieves reduction and/or suppression of normal-mode noise without additionally including one or more physical X capacitors as noise-measurement components, making it possible to reduce erroneous operations of peripheral devices around the inverter 13. The motor drive circuit 10D, which eliminates the need of physical X capacitors, results in a simpler configuration, making it possible to improve the reliability of the motor drive circuit 10D and the fabrication yield of the motor drive circuits 10D.

Making smaller the thickness of each of the first dielectric members 1c and 2c than that of the corresponding one of the second dielectric members 1d and 2d enables each power converter 17-5 to have formed the pseudo-X capacitor Cx between the input electrode A of the power card 1 and the input electrode B of the power card 2. This configuration is in particular of usefulness in a case where each of the dielectric members 1c, 1d, 2c, and 2d is formed of one or more materials having the same relative permittivity ε_{S}.

### Sixth Embodiment

The following describes a motor drive circuit 10E according to the sixth embodiment. The structure and/or functions of the motor drive circuit 10E according to the sixth embodiment are mainly identical to those of the motor drive circuit 10A of the second embodiment except for the following points. The following therefore describes mainly the different points.

The inverter 13 of the sixth embodiment includes power modules 17-6 in place of the power modules 17-2.

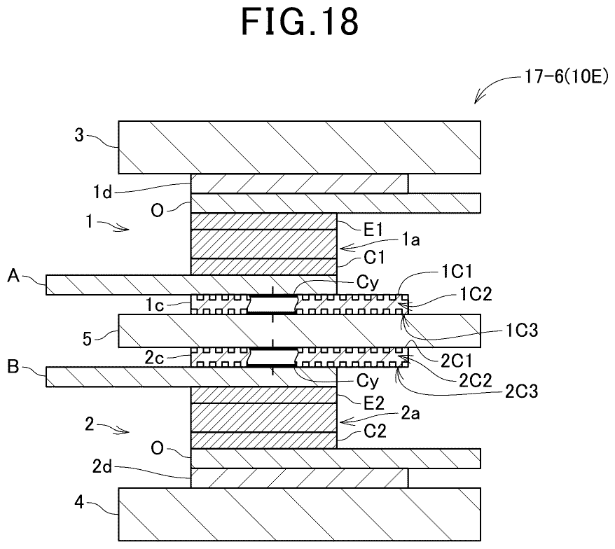

FIG. 18 is a sectional view of each power module 17-6 according to the sixth embodiment.

Referring to FIG. 18, each of the first and second dielectric members 1c and 1d of the first power card 1 included in each power module 17-6 has opposing first and second major surfaces; the first major surface, to which reference character 1c1 is assigned, of the first dielectric member 1c faces the upper-arm switch 1a, and the second major surface of the second dielectric member 1d faces the upper-arm switch 1a. Similarly, each of the first and second dielectric members 2c and 2d of the second power card 2 included in each power module 17-6 has opposing first and second major surfaces; the second major surface of the first dielectric member 2c, to which reference character 2c1 is assigned, faces the lower-arm switch 2a, and the first major surface of the second dielectric member 2d faces the lower-arm switch 2a.

Each power module 17-6 is configured such that the surface area of the first major surface 1c1 of the first dielectric member 1c, which faces the upper-arm switch 1a, is greater than the surface area of the second major surface of the second dielectric member 1d, which faces the upper-arm switch 1a. Additionally or alternatively, each power module 17-6 is configured such that the surface area of the second major surface 2c1 of the first dielectric member 2c, which faces the lower-arm switch 2a, is greater than the surface area of the first major surface of the second dielectric member 2d, which faces the lower-arm switch 2a.

For example, the first major surface 1c1 of the first dielectric member 1c has formed thereon projections and depressions 1c2. The first major surface 1c1 of the first dielectric member 1c can be interpreted as one surface of the first dielectric member 1c, which faces the upper-arm switch 1a, that is, faces the input termina A of the first power card 1.

Forming grooves in the first major surface 1c1 at intervals enables the projections and depressions 1c2 to be formed on the first major surface 1c1. Alternatively, forming projections on the first major surface 1c1 at intervals enables the projections and depressions 1c2 to be formed on the first major surface 1c1.

Similarly, the second major surface 2c1 of the first dielectric member 2c has formed thereon projections and depressions 2c2. The second major surface 2c1 of the first dielectric member 2c can be interpreted as one surface of the first dielectric member 2c, which faces the lower-arm switch 2a, that is, faces the input termina B of the second power card 2.

Forming grooves in the second major surface 2c1 at intervals enables the projections and depressions 2c2 to be formed on the second major surface 2c1. Alternatively, forming projections on the second major surface 2c1 at intervals enables the projections and depressions 2c2 to be formed on the second major surface 2c1.

The second major surface of the first dielectric member 1c, which faces the third heatsink 5, can have formed thereon projections and depressions 1c3. Similarly, the first major surface of the first dielectric member 2c, which faces the third heatsink 5, can have formed thereon projections and depressions 2c3.

Because the stray capacitance CK of a dielectric member is defined by the above formula of CK=ε₀ε_{S}SK/dK where ε_{S} represents a relative permittivity of the dielectric member. That is, the stray capacitance of each dielectric member is proportional to the surface area of the corresponding dielectric member, which faces the corresponding switching device, so that an increase in the surface area of the first major surface 1c1 of the first dielectric member 1c, which faces the upper-arm switch 1a, results in the stray capacitance C of the first dielectric member 1c increasing. The same applies to the first dielectric member 2c. That is, an increase in the surface area of the second major surface 2c1 of the first dielectric member 2c, which faces the lower-arm switch 2a, results in the stray capacitance C of the first dielectric member 2c increasing.

Making greater the surface area of each of the first major surface of the first dielectric member 1c and the surface area of the second major surface of the first dielectric member, which faces the corresponding one of the switches 1a and 2a, enables each of the first and second capacitors Cy illustrated in FIG. 18 to increase.

Accordingly, the motor drive circuit 10E achieves substantially the same advantageous benefits as stated above for the second embodiment. Additionally, the motor drive circuit 10E achieves an advantageous benefit of further reducing adverse effects due to common-mode noise on peripheral devices around the inverter 13.

Changing (i) the configurations of the projections and depressions formed on the first major surface of the first dielectric member 1c and (ii) the configurations of the projections and depressions formed on the second major surface of the first dielectric member 2c respectively enable (i) adjustment of the surface area of the first major surface and (ii) adjustment of the surface area of the second major surface, making it possible to determine a value of the stray capacitance of each of the first dielectric members 1c and 2c; the value of the stray capacitance is suitable for a frequency band of common-mode noise. This therefore enables the power modules 17-6 to be applied to various devices.

### Seventh Embodiment

The following describes a motor drive circuit 10F according to the seventh embodiment. The structure and/or functions of the motor drive circuit 10B according to the third embodiment are substantially identical to those of the motor drive circuit 10 except for the following points. The following therefore describes mainly the different points.

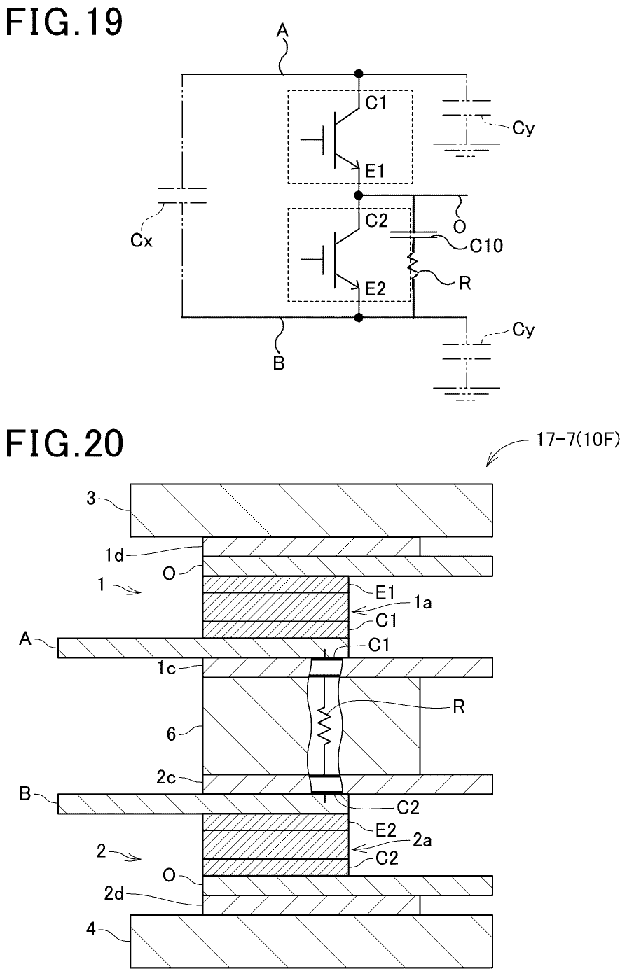

FIG. 19 illustrates an equivalent circuit of each power module 17-7 according to the seventh embodiment. FIG. 20 is a sectional view of each power module 17-7 according to the seventh embodiment.

The inverter 13 of the seventh embodiment includes power modules 17-7 in place of the power modules 17-3.

Each power module 17-7 of the seventh embodiment differs from the corresponding power module 17-3 of the third embodiment in that a pseudo resistor R is connected in series to the capacitor C10 serving as a pseudo snubber capacitor.

As illustrated in FIG. 20, each power module 17-7 includes a conductive member 6, which has, for example, a substantially plate-like shape, and the conductive member 6 is interposed between the first dielectric members 1c and 2c. The conductive member 6 forms the pseudo resistor R that can be interpreted as a pseudo snubber resistor different from a physical snubber resistor. A pseudo situation generated by the snubber resistor R represents, for example, a situation where, without physical snubber resistors, a resistor formed by the conductive member 6 included in the power module 17-7 equivalently serves as a physical snubber resistor. Such a pseudo snubber resistor can be interpreted as a resistor that absorbs high-frequency noise generated by on/off switching of the upper-arm switch 1a and/or the lower-arm switch 2a.

The conductive member 6 has opposing first and second major surfaces. The first major surface of the conductive member 6 is mounted on or located adjacently to the second major surface of the first dielectric member 1c, and the second major surface of the conductive member 6 is mounted on or located adjacently to the first major surface of the first dielectric member 2c.

That is, the first dielectric member 1c, the conductive member 6, and the first dielectric member 2c are arranged in the stacking direction, so that the stray capacitance C11 arising from the first dielectric member 1c, the resistor R based on the conductive member 6, and the stray capacitance C21 arising from the first dielectric member 2c are connected in series, that is, the pseudo snubber capacitor C10, which is the sum of the stray capacitances C11 and C21, and the pseudo resistor R are connected in series. Each of the input electrode A, the input electrode B, the output electrodes O, and the conductive member 6 has an electrical conductivity, and the electrical conductivity of the conductive member 6 is smaller than any other electrical conductivities of the input electrode A, the input electrode B, and the output electrodes O. For example, copper, gold, or silver can be used as a material for each of the input electrode A, the input electrode B, and the output electrodes O, and bronze, chrome, stainless, or lead can be used as a material for the conductive member 6.

This configuration of the motor drive circuit 10F enables a part of noise generated from the switches 1a and 2a of each power module 17-7 to flow into the capacitor C10 and the resistor R to accordingly prevent the part of noise from flowing out the input side of motor drive circuit 10F, resulting in the part of noise being collected in the corresponding power module 17-7. Resistance components included in each power module 17-7 can attenuate the noise collected in the corresponding power module 17-7.

The motor drive circuit 10F therefore achieves reduction and/or suppression of noise generated due to switching operations of the switches 1a and 2a without additionally including one or more physical snubber capacitors and snubber resistors as noise-measurement components, making it possible to reduce erroneous operations of peripheral devices around the inverter 13.

The motor drive circuit 10F, which eliminates the need of physical snubber capacitors and physical snubber resistors, results in a simpler configuration, making it possible to improve the reliability of the motor drive circuit 10F and the fabrication yield of the motor drive circuits 10F.

If one or more snubber resistors were provided in the inverter 13, the one or more snubber resistors might serve as one or more heating elements so that heat-dissipation measurement might be needed for the inverter 13.

In contrast, each power module 17-7 of the motor drive circuit 10F of the seventh embodiment is configured to include the pseudo snubber resistor R. This configuration enables the first and second heatsinks 3 and 4 included in each power module 17-7 to dissipate heat generated from the pseudo snubber resistor R, resulting in no need of heat-dissipation measurement for physical snubber resistors. This therefore results in the motor drive circuit 10F having a simpler configuration.

Each embodiment uses an IGBT as each of the upper- and lower-arm switching elements 1a and 2a, but can use another transistor except for such an IGBT.

The power modules 17-1 to 17-7 described in the respective embodiments can be preferably applied to relatively high switching-speed inverters, such as inverters to be installed in electric vehicles (EV) or inverters to be installed in railroad vehicles. Additionally, the power modules 17-1 to 17-7 described in the respective embodiments can be applied to various power converters, such as boost converters, buck converters, buck-boost converters, and/or forward discharge converters (FDC).

Each of the power modules 17-1 to 17-7 is configured such that the power cards 1 and 2 are stacked in a predetermined stacking direction, but the present disclosure is not limited thereto. Specifically, the dielectric members and switches included in each of the power modules 17-1 to 17-7 can be aligned horizontally on at least one plane, such as at least one major surface of a plate-like base.

Each of the power cards and the heatsinks is not limited to the rectangular plate-like shape, and therefore can have another shape.

The subject matters of the respective power modules 17-1 to 17-7 can be freely combined with each other. For example, the first and second capacitors Cy can be formed in each of the power modules 17-1 and 17-3 (see FIGS. 3 and 11), and the capacitor Cx can be formed in each of the power modules 17-2 to 17-4 (see FIGS. 7, 11, and 15).

While illustrative embodiments of the present disclosure have been described herein, the present disclosure is not limited to the embodiments described herein. Specifically, the present disclosure includes any and all embodiments having modifications, omissions, combinations (e.g., of aspects across various embodiments), adaptations and/or alternations as would be appreciated by those in the art based on the present disclosure.

The limitations in the claims are to be interpreted broadly based on the language employed in the claims and not limited to examples described in the present specification or during the prosecution of the application, which examples are to be construed as non-exclusive.

The present disclosure includes the following first to fourteenth technological concepts.

The first technological concept is a power module (17-1, 17-2, 17-3, 17-4, 17-5).

The power module (17-1, 17-2, 17-3, 17-4, 17-5) includes an upper-arm switching device (1), and a lower-arm switching device (2) located to face the upper-arm switching device. The power module (17-1) includes a first dielectric member (1c, 2c) having a first stray capacitance. The first dielectric member is located in a space defined by the upper-arm switching device and the lower-arm switching device. The power module includes a second dielectric member (1d, 2d) having a second stray capacitance. The second dielectric member is located to be separated from the space. The second stray capacitance is different from the first stray capacitance.

In the power module according to the second technological concept, which depends from the first technological concept, the first stray capacitance of the first dielectric member is adjusted to be higher than the second stray capacitance of the second dielectric member.

In the power module according to the third technological concept, which depends from the first or second technological concept, each of the first and second switching devices has opposing first and second surfaces. The first dielectric member is located between one of the first and second surfaces of the upper-arm switching device and one of the first and second surfaces of the lower-arm switching device. The power module further includes a cooling member (3, 4) provided for one of the upper- and lower-arm switching devices. The second dielectric member is located between the cooling member and the other of the first and second surface of the one of the upper- and lower-arm switching devices.

The power module according to the fourth technological concept, which depends from any one of the first to third technological concepts, further includes an intermediate cooling member (5) disposed between the upper-arm switching device and the lower-arm switching device. The first dielectric member is located between the intermediate cooling member and one of the upper- and lower-arm switching devices.

In the power module according to the fifth technological concept, which depends from the first technological concept, the second stray capacitance of the second dielectric member is adjusted to be higher than the first stray capacitance of the first dielectric member.

In the power module according to the sixth technological concept, which depends from the fifth technological concept, each of the first and second switching devices has opposing first and second surfaces. The first dielectric member is located between one of the first and second surfaces of the upper-arm switching device and one of the first and second surfaces of the lower-arm switching device. The power module further includes a cooling member (3, 4) provided for one of the upper- and lower-arm switching devices. The second dielectric member is located between the cooling member and the other of the first and second surface of the one of the upper- and lower-arm switching devices.

In the power module according to the seventh technological concept, which depends from the first technological concept, the upper- and lower-arm switching devices are aligned in a predetermined alignment direction. Each of the first and second dielectric members has a thickness in the alignment direction. The thickness of the first dielectric member is set to be smaller than the thickness of the second dielectric member.

In the power module according to the eighth technological concept, which depends from the first technological concept, the first dielectric member and the second dielectric members are located to face one of the upper- and lower-arm switching devices. The first dielectric member has opposing first and second surfaces. One of the first and second surfaces of the first dielectric member is located to face the one of the upper- and lower-arm switching devices. The second dielectric member has opposing first and second surfaces. One of the first and second surfaces of the second dielectric member is located to face the one of the upper- and lower-arm switching devices. The one of the first and second surfaces of the first dielectric member is set to be wider than the one of the first and second surfaces of the second dielectric member.

In the power module according to the ninth technological concept, which depends from the eighth technological concept, the one of the first and second surfaces of the first dielectric member has formed projections and depressions (1c2, 2c2).

In the power module according to the tenth technological concept, which depends from the first technological concept, each of the upper- and lower-arm switching devices includes an input portion (A, B) serving as input of power thereto, and an output portion (O) serving as output of power therefrom. The first dielectric member is located between the output portion of the upper-arm switching device and the input portion of the lower-arm switching device.

The power module according to the eleventh technological concept, which depends from the tenth technological concept, further includes a conductive member (6) located adjacent to the first dielectric member. Each of the input and output portions of each of the upper- and lower-arm switching devices has an electrical conductivity. The conductive member has an electrical conductivity. The electrical conductivity of the conductive member is set to be lower than the electrical conductivity of each of the input and output portions of each of the upper- and lower-arm switching devices.

The twelfth technological concept is a power module (17-1, 17-2, 17-3, 17-4, 17-5). The power module according to the twelfth technological concept includes a switch unit (1, 2) that includes (i) a pair of upper- and lower-arm switches (1a, 2a) connected in series, (ii) a first input portion (A) connected to a positive electrode of a power supply (11), (iii) a second input portion (B) connected to a negative electrode of the power supply, and (iv) an output portion (O) connected to a load.

The power module according to the twelfth technological concept includes at least one dielectric member (1c, 2c, 1d, 2d) having an adjusted stray capacitance and located at least one of (i) between the first and second input portions and (ii) between at least one of the first and second input portions and a member (5, FG2) having a ground potential. The at least one dielectric member constitutes at least one route that transfers at least one of normal-mode noise and common-mode noise into the power module.

The power module according to the thirteenth technological concept, which depends from the twelfth technological concept, further includes at least one cooling member located to cool the switch unit. The at least one dielectric member includes a first dielectric member (1c, 2c) located between the first and second input portions (A, B) and having a first stray capacitance as the adjusted stray capacitance. The at least one dielectric member includes a second dielectric member (1d, 2d) located between the output terminal (O) and the at least one cooling member (3, 4) and having a second stray capacitance as the adjusted stray capacitance. The first stray capacitance of the first dielectric member is adjusted to be higher than the second stray capacitance of the second dielectric member. The first dielectric member serves as a normal-mode noise transferring route as the at least one route. The normal-mode noise transferring route is configured to transfer the normal mode noise into the power module.

The power module according to the fourteenth technological concept, which depends from the twelfth technological concept, further includes at least one cooling member (3, 4) located to cool the switch unit, and an intermediate cooling member (5) disposed between the upper-arm switch and the lower-arm switch. The intermediate cooling member serves as the member having the ground potential. The at least one dielectric member includes a first dielectric member (1c, 2c) located between at least one of the first and second input portions and the intermediate cooling member and having a first stray capacitance as the adjusted stray capacitance. The at least one dielectric member includes a second dielectric member (1d, 2d) located between the output terminal and the at least one cooling member and having a second stray capacitance as the adjusted stray capacitance. The first stray capacitance of the first dielectric member is adjusted to be higher than the second stray capacitance of the second dielectric member. The first dielectric member serves as a common-mode noise transferring route as the at least one route. The common-mode noise transferring route is configured to transfer the common mode noise into the power module.

1. A power module comprising:
an upper-arm switching device;
a lower-arm switching device located to face the upper-arm switching device;
a first dielectric member having a first stray capacitance, the first dielectric member being located in a space defined by the upper-arm switching device and the lower-arm switching device; and
a second dielectric member having a second stray capacitance, the second dielectric member being located to be separated from the space, the second stray capacitance being different from the first stray capacitance.

2. The power module according to claim 1, wherein:
the first stray capacitance of the first dielectric member is adjusted to be higher than the second stray capacitance of the second dielectric member.

3. The power module according to claim 2, wherein:
each of the first and second switching devices has opposing first and second surfaces; and
the first dielectric member is located between one of the first and second surfaces of the upper-arm switching device and one of the first and second surfaces of the lower-arm switching device,
the power module further comprising:
a cooling member provided for one of the upper- and lower-arm switching devices,
the second dielectric member being located between the cooling member and the other of the first and second surface of the one of the upper- and lower-arm switching devices.

4. The power module according to claim 1, further comprising:
an intermediate cooling member disposed between the upper-arm switching device and the lower-arm switching device, wherein:
the first dielectric member is located between the intermediate cooling member and one of the upper- and lower-arm switching devices.

5. The power module according to claim 1, wherein:
the second stray capacitance of the second dielectric member is adjusted to be higher than the first stray capacitance of the first dielectric member.

6. The power module according to claim 5, wherein:
each of the first and second switching devices has opposing first and second surfaces; and
the first dielectric member is located between one of the first and second surfaces of the upper-arm switching device and one of the first and second surfaces of the lower-arm switching device, the power module further comprising:
a cooling member provided for one of the upper- and lower-arm switching devices,
the second dielectric member being located between the cooling member and the other of the first and second surface of the one of the upper- and lower-arm switching devices.

7. The power module according to claim 1, wherein:
the upper- and lower-arm switching devices are aligned in a predetermined alignment direction;
each of the first and second dielectric members has a thickness in the alignment direction; and
the thickness of the first dielectric member is set to be smaller than the thickness of the second dielectric member.

8. The power module according to claim 1, wherein:
the first dielectric member and the second dielectric member are located to face one of the upper- and lower-arm switching devices;
the first dielectric member has opposing first and second surfaces;
one of the first and second surfaces of the first dielectric member is located to face the one of the upper- and lower-arm switching devices;
the second dielectric member has opposing first and second surfaces;
one of the first and second surfaces of the second dielectric member is located to face the one of the upper- and lower-arm switching devices;
the one of the first and second surfaces of the first dielectric member is set to be wider than the one of the first and second surfaces of the second dielectric member.

9. The power module according to claim 8, wherein:
the one of the first and second surfaces of the first dielectric member has formed projections and depressions.

10. The power module according to claim 1, wherein:
each of the upper- and lower-arm switching devices comprises:
an input portion serving as input of power thereto; and
an output portion serving as output of power therefrom; and
the first dielectric member is located between the output portion of the upper-arm switching device and the input portion of the lower-arm switching device.

11. The power module according to claim 10, further comprising:
a conductive member located adjacent to the first dielectric member, wherein;
each of the input and output portions of each of the upper- and lower-arm switching devices has an electrical conductivity;
the conductive member has an electrical conductivity; and
the electrical conductivity of the conductive member is set to be lower than the electrical conductivity of each of the input and output portions of each of the upper- and lower-arm switching devices.

12. A power module comprising:
a switch unit comprising:
a pair of upper- and lower-arm switches connected in series;
a first input portion connected to a positive electrode of a power supply;
a second input portion connected to a negative electrode of the power supply; and
an output portion connected to a load; and
at least one dielectric member having an adjusted stray capacitance and located at least one of (i) between the first and second input portions and (ii) between at least one of the first and second input portions and a member having a ground potential,
the at least one dielectric member constituting at least one route that transfers at least one of normal-mode noise and common-mode noise into the power module.

13. The power module according to claim 12, further comprising:
at least one cooling member located to cool the switch unit, wherein:
the at least one dielectric member comprises:
a first dielectric member located between the first and second input portions and having a first stray capacitance as the adjusted stray capacitance; and
a second dielectric member located between the output terminal and the at least one cooling member and having a second stray capacitance as the adjusted stray capacitance;
the first stray capacitance of the first dielectric member is adjusted to be higher than the second stray capacitance of the second dielectric member; and
the first dielectric member serving as a normal-mode noise transferring route as the at least one route, the normal-mode noise transferring route being configured to transfer the normal mode noise into the power module.

14. The power module according to claim 12, further comprising:
at least one cooling member located to cool the switch unit; and
an intermediate cooling member disposed between the upper-arm switch and the lower-arm switch, the intermediate cooling member serving as the member having then ground potential, wherein:
the at least one dielectric member comprises:
a first dielectric member located between at least one of the first and second input portions and the intermediate cooling member and having a first stray capacitance as the adjusted stray capacitance; and
a second dielectric member located between the output terminal and the at least one cooling member and having a second stray capacitance as the adjusted stray capacitance;
the first stray capacitance of the first dielectric member is adjusted to be higher than the second stray capacitance of the second dielectric member; and
the first dielectric member serving as a common-mode noise transferring route as the at least one route, the common-mode noise transferring route being configured to transfer the common mode noise into the power module.
